(19) United States
(12) Patent Application Publication
(10) Pub. No.: US 2016/0076149 A1
(43) Pub. Date: Mar. 17, 2016

(54) SUBSTRATE PROCESSING APPARATUS, METHOD OF MANUFACTURING SEMICONDUCTOR DEVICE AND FURNACE LID

(71) Applicant: HITACHI KOKUSAI ELECTRIC INC., Tokyo (JP)

(72) Inventors: Keishin YAMAZAKI, Toyama-shi (JP); Manabu IZUMI, Toyama-shi (JP); Katsuaki NOGAMI, Toyama-shi (JP)

(73) Assignee: HITACHI KOKUSAI ELECTRIC INC., Tokyo (JP)

(21) Appl. No.: 14/949,714

(22) Filed: Nov. 23, 2015

Related U.S. Application Data
(63) Continuation of application No. PCT/JP2014/064263, filed on May 29, 2014.

(30) Foreign Application Priority Data
May 31, 2013 (JP) 2013-116106

(51) Int. Cl. C23C 16/52; F27D 1/18; C23C 16/455; H01L 21/02; C23C 16/46; C23C 16/44

(52) U.S. Cl. CPC C23C 16/52; C23C 16/46; C23C 16/4412; C23C 16/455; H01L 21/02271; F27D 1/1816

(57) ABSTRACT

By suppressing a re-liquefaction of a processing gas in a reaction tube, the processing gas is maintained in a gaseous state. There is provided a substrate processing apparatus that includes a reaction tube, a supply unit, an exhaust unit, a first heating unit configured to heat a substrate in the reaction tube, a second heating unit configured to heat a downstream portion of a reactant in gaseous state flowing in the reaction tube from the supply unit toward the exhaust unit, and a furnace lid, wherein the furnace lid includes a heat absorbing unit facing a lower surface of a lower end portion of the reaction tube and being heated by the second heating unit, the heat absorbing unit having an outer perimeter surface disposed outer than an inner circumference surface of the lower end portion.

### CROSS-REFERENCE TO RELATED PATENT APPLICATION

This non-provisional U.S. patent application claims priority under 35 U.S.C. §119 of Japanese Patent Application No. 2013-116106, filed on May 31, 2013, and PCT/JP2014/064263, filed on May 29, 2014, the entire contents of which are hereby incorporated by reference.

### BACKGROUND OF THE INVENTION

1. Field of the Invention

The present invention relates to a substrate processing apparatus, a method of manufacturing a semiconductor device and a furnace lid.

2. Description of the Related Art

Conventionally, as one of processes of manufacturing a semiconductor device such as a dynamic random access memory (DRAM) or the like, a process in which a processing gas is supplied into a reaction tube in which a substrate is loaded to form an oxide film on a surface of the substrate may be performed. Such a process is performed by a substrate processing apparatus that includes, for example, a reaction tube configured to accommodate and process the substrate, a supply unit configured to supply a processing gas obtained by vaporizing a liquid source onto the substrate in the reaction tube, and a heating unit configured to heat the substrate accommodated in the reaction tube.

### SUMMARY OF THE INVENTION

However, in the substrate processing apparatus, a low-temperature region which is difficult for the heating unit to heat may be generated in the reaction tube. When a processing gas passes through the low-temperature region, the processing gas may be cooled to a lower temperature than an evaporation point to be re-liquefied.

The present invention provides a substrate processing apparatus in which re-liquefaction of a processing gas in a reaction tube is suppressed and the processing gas in the reaction tube is maintained in a gaseous state, a method of manufacturing a semiconductor device and a furnace lid.

According to an aspect of the present invention, there is provided a substrate processing apparatus including:

a reaction tube where a substrate is processed;

a supply unit configured to supply a reactant to the substrate;

an exhaust unit configured to exhaust an inside atmosphere of the reaction tube;

a first heating unit configured to heat the substrate in the reaction tube;

a second heating unit configured to heat a downstream portion of the reactant in gaseous state flowing in the reaction tube from the supply unit toward the exhaust unit; and

a furnace lid configured to cover a lower end portion of the reaction tube, wherein the furnace lid comprises a heat absorbing unit facing a lower surface of the lower end portion and being heated by the second heating unit, the heat absorbing unit having an outer perimeter surface disposed outer than an inner circumference surface of the lower end portion.

### BRIEF DESCRIPTION OF THE DRAWINGS

FIG. 1 is a cross-sectional view schematically illustrating a substrate processing apparatus according to an embodiment of the present invention.

FIG. 2 is a longitudinal cross-sectional view schematically illustrating a furnace included in a substrate processing apparatus according to an embodiment of the present invention.

FIG. 3 is a cross-sectional view schematically illustrating a portion about a furnace according to an embodiment of the present invention.

FIG. 4 is a cross-sectional view schematically illustrating a portion about a furnace according to another embodiment of the present invention.

FIG. 5 is a cross-sectional view schematically illustrating a portion about a furnace according to still another embodiment of the present invention.

FIG. 6 is a cross-sectional view schematically illustrating a portion about a furnace preferably used in an embodiment of the present invention.

FIG. 7 is a block diagram schematically illustrating a controller of a substrate processing apparatus preferably used in an embodiment of the present invention.

FIG. 8 is a flow diagram chart illustrating a substrate processing process according to an embodiment of the present invention.

FIG. 9 is a cross-sectional view schematically illustrating a portion about a furnace according to a comparative example of the present invention.

### DETAILED DESCRIPTION OF THE PREFERRED EMBODIMENTS

### An Embodiment of the Present Invention

Hereinafter, an embodiment of the present invention will be described with reference to the drawings.

(1) Configuration of Substrate Processing Apparatus

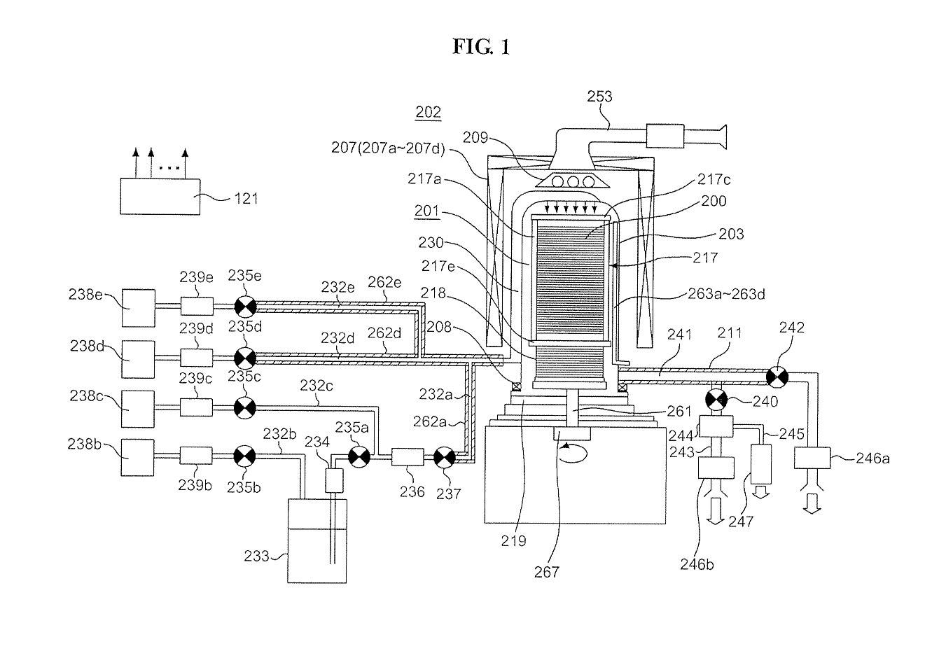

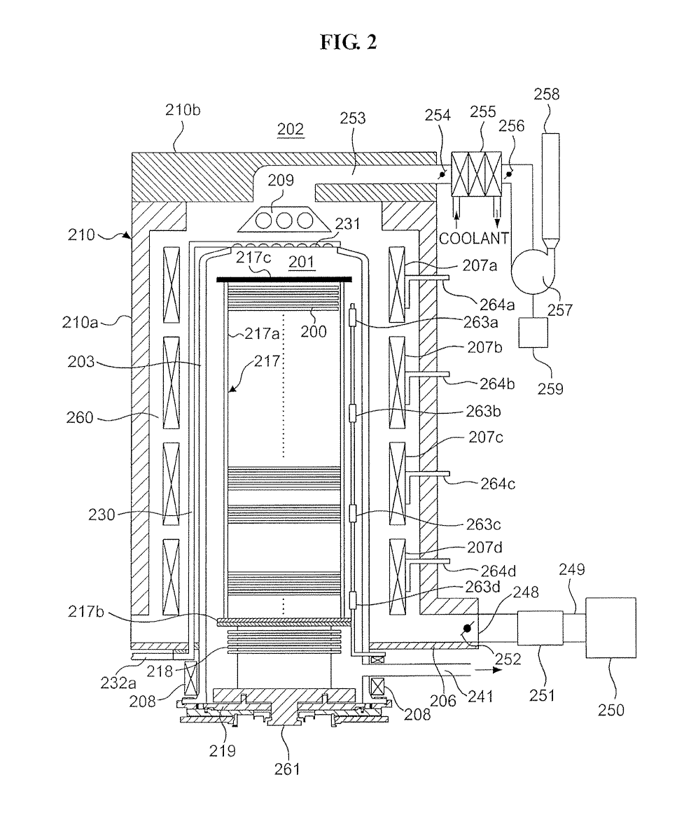

First, a configuration of a substrate processing apparatus according to the present embodiment will be mainly described with reference to FIGS. 1 and 2. FIG. 1 is a cross-sectional view schematically illustrating the substrate processing apparatus according to the present embodiment and is a longitudinal cross-sectional view illustrating a treatment furnace 202. FIG. 2 is a longitudinal cross-sectional view schematically illustrating the treatment furnace 202 included in the substrate processing apparatus according to the present embodiment.

(Reaction Tube)

Referring to FIG. 1, the treatment furnace 202 includes a reaction tube 203. The reaction tube 203 is made of, for example, a heat-resistant material such as quartz (SiO₂) or silicon carbide (SiC), and is formed in a cylindrical shape whose upper end and lower end are open. A processing chamber 201 is formed in a cylindrical hollow portion of the reaction tube 203 and is configured to accommodate wafers 200 serving as substrates in a horizontal posture to be arranged on multiple stages in a vertical direction by a boat 217 to be described below.

Below the reaction tube 203, a seal cap 219 capable of air-tightly sealing (closed) a lower end opening (a furnace) of the reaction tube 203 is provided as a furnace lid. The seal cap 219 is configured to abut a lower end of the reaction tube 203 in a vertical direction from a lower portion thereof. The seal cap 219 is formed to have a disk shape. Also, the seal cap 219 is formed of a metal, such as stainless steel (SUS) and the like, or quartz.

The boat 217 serving as a substrate retainer is configured to hold the plurality of wafers 200 on multiple stages. The boat 217 includes a plurality of holders 217a (e.g., three holders) which hold the plurality of wafers 200. The plurality of holders 217a are each installed between a bottom plate 217b and a top plate 217c. The plurality of wafers 200 are arranged in a horizontal posture while the centers thereof are aligned and held in a tube-axis direction on multiple stages. The top plate 217c is formed to be larger than a maximum outer diameter of the wafer 200 to be held in the boat 217.

As a material of the holder 217a and the top plate 217c, for example, a non-metallic material having good thermal conductivity, such as silicon carbide (SiC), aluminum oxide (AlO), aluminum nitride (AlN), silicon nitride (SiN), zirconium oxide (ZrO) and the like, may be used. Specifically, a non-metallic material having a thermal conductivity of 10 W/mK or more may be used. Also, the holder 217a may be formed of a metal, such as SUS and the like, or quartz. When the metal is used as the material of the holder 217a and the top plate 217c, a Teflon (registered trademark) process may be preferably performed on the metal.

Below the boat 217, insulators 218 made of, for example, a heat-resistant material such as quartz, silicon carbide (SiC) or the like, are provided, and are configured such that heat from a first heating unit 207 is difficult to be transferred to the seal cap 219. The insulator 218 serves as an insulating member and as a retainer which holds the boat 217. Also, the insulators 218 are not limited to a plurality of insulating plates formed in a disk shape as illustrated in FIG. 2, which are provided in a horizontal posture and on multiple stages, and may be, for example, a quartz cap formed in a cylindrical shape. Also, the insulator 218 may be considered as one of configuration members of the boat 217.

Below the reaction tube 203, a boat elevator serving as a lifting mechanism, which lifts the boat 217 to load into or unload from the reaction tube 203, is provided. The seal cap 219 configured to seal the furnace when the boat 217 is lifted by the boat elevator is provided in the boat elevator.

A boat rotating mechanism 267 configured to rotate the boat 217 is provided in a direction opposite the processing chamber 201 based on the seal cap 219. A rotary shaft 261 of the boat rotating mechanism 267 passes through the seal cap 219 to be connected to the boat 217 and is configured to rotate the wafer 200 by rotating the boat 217.

(First Heating Unit)

Outside the reaction tube 203, the first heating unit 207 configured to heat the wafer 200 in the reaction tube 203 is provided to concentrically surround a side wall of the reaction tube 203. The first heating unit 207 is supported and provided by a heater base 206. As illustrated in FIG. 2, the first heating unit 207 includes a first heater unit 207a, a second heater unit 207b, a third heater unit 207c and a fourth heater unit 207d. The heating units 207a, 207b, 207c and 207d are provided along a direction in which the wafers 200 in the reaction tube 203 are stacked.

In the reaction tube 203, a first temperature sensor 263a, a second temperature sensor 263b, a third temperature sensor 263c and a fourth temperature sensor 263d, which are configured as, for example, a thermocouple corresponding to each heating unit, are provided. The temperature sensors 263a through 263d are each provided between the reaction tube 203 and the boat 217. Also, each of the temperature sensors 263a through 263d may be provided to detect a temperature of the wafer 200 located at the center of the plurality of wafers 200 heated by each heating unit.

A controller 121 to be described below is electrically connected to the first heating unit 207 and each of the temperature sensors 263a through 263d. The controller 121 controls a power supplied to the first heater unit 207a, the second heater unit 207b, the third heater unit 207c and the fourth heater unit 207d at a predetermined timing based on temperature information detected by each of the temperature sensors 263a through 263d such that the temperature of the wafer 200 in the reaction tube 203 becomes a predetermined temperature. Thus, the first heater unit 207a, the second heater unit 207b, the third heater unit 207c and the fourth heater unit 207d are configured such that temperature settings or regulations are individually performed.

(Supply Unit)

Referring to FIGS. 1 and 2, a supply nozzle 230 through which a reactant passes is provided between the reaction tube 203 and the first heating unit 207. Here, the reactant refers to a material which is supplied onto the wafer 200 in the reaction tube 203 and reacts with the wafer 200. As the reactant, for example, hydrogen peroxide (H₂O₂) or water (H₂O) used as an oxidizing agent may be used. The supply nozzle 230 is formed of, for example, quartz having low thermal conductivity. The supply nozzle 230 may have a double-tube structure. The supply nozzle 230 is provided along a side portion of an outer wall of the reaction tube 203. An upper end (downstream end) of the supply nozzle 230 is air-tightly provided in a top portion (upper end opening) of the reaction tube 203. In the supply nozzle 230 disposed in the upper end opening of the reaction tube 203, a plurality of supply holes 231 are provided from the upstream end to the downstream end (see FIG. 2). The supply holes 231 are formed such that the reactant supplied into the reaction tube 203 is injected toward the top plate 217c of the boat 217 accommodated in the reaction tube 203.

A downstream end of a reactant supply pipe 232a configured to supply the reactant is connected to the upstream end of the supply nozzle 230. In the reactant supply pipe 232a, a reactant supply tank 233, a liquid mass flow controller (LMFC) 234 serving as a liquid flow rate controller (liquid flow rate control unit), a valve 235a serving as an opening and closing valve, a separator 236 and a valve 237 serving as an opening and closing valve are sequentially provided from an upstream end. Also, a sub-heater 262a is provided downstream from at least the valve 237 of the reactant supply pipe 232a.

A downstream end of a pressurized gas supply pipe 232b configured to supply a pressurized gas is connected to an upper portion of the reactant supply tank 233. In the pressurized gas supply pipe 232b, a pressurized gas supply source 238b, an MFC 239b serving as a flow rate controller (flow rate control unit) and a valve 235b serving as an opening and closing valve are sequentially provided from an upstream end.

An inert gas supply pipe 232c is connected between the valve 235a of the reactant supply pipe 232a and the separator 236. In the inert gas supply pipe 232c, an inert gas supply source 238c, an MFC 239c serving as a flow rate controller (flow rate control unit) and a valve 235c serving as an opening and closing valve are sequentially provided from an upstream end.

A downstream end of the first gas supply pipe 232d is connected downstream from the valve 237 of the reactant supply pipe 232a. In the first gas supply pipe 232d, a source gas supply source 238d, an MFC 239d serving as a flow rate controller (flow rate control unit) and a valve 235d serving as an opening and closing valve are sequentially provided from an upstream end. A sub-heater 262d is provided downstream from at least the valve 235d of the first gas supply pipe 232d. A downstream end of second gas supply pipe 232e is connected downstream from the valve 235d of the first gas supply pipe 232d. In the second gas supply pipe 232e, a source gas supply source 238e, an MFC 239e serving as a flow rate controller (flow rate control unit) and a valve 235e serving as an opening and closing valve are sequentially provided from an upstream end. A sub-heater 262e is provided downstream from at least the valve 235e of the second gas supply pipe 232e.

A reactant supply system mainly includes the reactant supply pipe 232a, the LMFC 234, the valve 235a, the separator 236, the valve 237 and the supply nozzle 230. Also, the reactant supply tank 233, the pressurized gas supply pipe 232b, the inert gas supply source 238b, the MFC 239b or the valve 235b may be considered as included in the reactant supply system. The supply unit mainly includes the reactant supply system.

Also, an inert gas supply system mainly includes the inert gas supply pipe 232c, the MFC 239c and the valve 235c. Also, the inert gas supply source 238c, the reactant supply pipe 232a, the separator 236, the valve 237 or the supply nozzle 230 may be considered as included in the inert gas supply system. Also, a first gas supply system mainly includes the first gas supply pipe 232d, the MFC 239d and the valve 235d. Also, the source gas supply source 238d, the reactant supply pipe 232a or the supply nozzle 230 may be considered as included in the first gas supply system. Also, a second gas supply system mainly includes the second gas supply pipe 232e, the MFC 239e and the valve 235e. Also, the source gas supply source 238e, the reactant supply pipe 232a or the supply nozzle 230 may be considered as included in the second gas supply system. Also, the inert gas supply system, the first gas supply system and the second gas supply system may be considered as included in the supply unit.

(State Conversion Unit)

A third heating unit 209 is provided on an upper portion of the outside of the reaction tube 203. The third heating unit 209 is configured to heat the top plate 217c of the boat 217. As the third heating unit 209, for example, a lamp heater unit or the like may be used. The controller 121 to be described below is electrically connected to the third heating unit 209. The controller 121 is configured to control a power supplied to the third heating unit 209 at a predetermined timing such that the top plate 217c of the boat 217 becomes a predetermined temperature. A state conversion unit mainly includes the third heating unit 209 and the top plate 217c. The state conversion unit converts, for example, the reactant in a liquid state supplied in the reaction tube 203 or a liquid source generated by dissolving the reactant in a solvent into the reactant in a gaseous state. Also, hereinafter, these reactants are collectively and simply referred to as the reactants in a liquid state.

Hereinafter, for example, an operation in which a reactant in a liquid state is vaporized and a processing gas (vaporizing gas) is generated will be described. First, a pressurized gas is supplied into the reactant supply tank 233 through the pressurized gas supply pipe 232b via the MFC 239b and the valve 235b. Thus, a liquid source accumulated in the reactant supply tank 233 is delivered into the reactant supply pipe 232a. The liquid source supplied into the reactant supply pipe 232a from the reactant supply tank 233 is supplied into the reaction tube 203 through the LMFC 234, the valve 235a, the separator 236, the valve 237 and the supply nozzle 230. When the liquid source supplied into the reaction tube 203 is brought in contact with the top plate 217c heated by the third heating unit 209, the liquid source is vaporized or misted and a processing gas (vaporized gas or mist gas) is generated. The processing gas is supplied to the wafer 200 in the reaction tube 203 and a predetermined substrate processing is performed on the wafer 200.

Also, in order to promote the vaporization of the reactant in a liquid state, the reactant in the liquid state flowing through the reactant supply pipe 232a may be pre-heated by the sub-heater 262a. Thus, the reactant in the liquid state may be supplied into the reaction tube 203 in a state in which the vaporization is more easily performed.

(Exhaust Unit)

An upstream end of a first exhaust tube 241 configured to exhaust atmosphere of the reaction tube 203 [in the processing chamber 201] is connected to the reaction tube 203. In the first exhaust tube 241, a pressure sensor serving as a pressure detector (pressure detection unit) configured to detect a pressure in the reaction tube 203, an auto pressure controller (APC) valve 242 serving as a pressure regulator (pressure regulating unit) and a vacuum pump 246a serving as a vacuum-exhaust device are sequentially provided from an upstream end. The first exhaust tube 241 is configured to be vacuum-exhausted by the vacuum pump 246a such that the pressure in the reaction tube 203 becomes a predetermined pressure (degree of vacuum). Also, the APC valve 242 is an opening and closing valve that may perform vacuum-exhausting and vacuum-exhausting stop in the reaction tube 203 by opening or closing the valve and regulate a pressure therein by adjusting a degree of valve opening.

An upstream end of a second exhaust tube 243 is connected upstream from the APC valve 242 of the first exhaust tube 241. In the second exhaust tube 243, a valve 240 serving as an opening and closing valve, a separator 244 configured to separate an exhaust gas exhausted through the reaction tube 203 into liquid and gas and a vacuum pump 246b serving as a vacuum-exhaust device are sequentially provided from an upstream end. An upstream end of a third exhaust tube 245 is connected to the separator 244 and a liquid recovery tank 247 is provided in the third exhaust tube 245. As the separator 244, for example, gas chromatography or the like may be used.

An exhaust unit mainly includes the first exhaust tube 241, the second exhaust tube 243, the separator 244, the liquid recovery tank 247, the APC valve 242, the valve 240 and the pressure sensor. Also, the vacuum pump 246a or the vacuum pump 246b may be considered as included in the exhaust unit.

(Reaction Tube Cooling Unit)

As illustrated in FIG. 2, an insulating member 210 is provide on an outer circumference of the first heating unit 207 such that the reaction tube 203 and the first heating unit 207 are covered. The insulating member 210 may include a side portion insulating member 210a provided to surround the side wall of the reaction tube 203 and an upper portion insulating member 210b provided to cover the upper end of the reaction tube 203. The side portion insulating member 210a and the upper portion insulating member 210b are air-tightly connected. Also, the insulating member 210 may include the side portion insulating member 210a and the upper portion insulating member 210b, which are integrally formed. The insulating member 210 is made of a heat-resistant material such as quartz or silicon carbide.

Below the side portion insulating member 210a, a supply port 248 configured to supply a cooling gas is formed. Also, in the present embodiment, although the supply port 248 is formed by a lower end portion of the side portion insulating member 210a and the heater base 206, the supply port 248 may be formed, for example, by providing an opening in the side portion insulating member 210a. A downstream end of the cooling gas supply pipe 249 is connected to the supply port 248. In the cooling gas supply pipe 249, a cooling gas supply source 250, an MFC 251 serving as a flow rate controller (flow rate control unit) and a shutter 252 serving as a shut-off valve are sequentially provided from an upstream end.

A cooling gas supply system mainly includes the cooling gas supply pipe 249 and the MFC 251. Also, the cooling gas supply source 250 or the shutter 252 may be considered as included in the cooling gas supply system.

An upstream end of a cooling gas exhaust tube 253 configured to exhaust atmosphere in a space 260 between the reaction tube 203 and the insulating member 210 is connected to the upper portion insulating member 210b. In the cooling gas exhaust tube 253, a shutter 254 serving as a shut-off valve, a radiator 255 configured to cool the exhaust gas flowing in the cooling gas exhaust tube 253 by circulating cooling water, a shutter 256 serving as a shut-off valve, a blower 257 configured to flow the exhaust gas from an upstream of the cooling gas exhaust tube 253 to a downstream thereof and an exhaust mechanism 258 including an exhaust port configured to discharge the exhaust gas to an outside of the treatment furnace 202 are sequentially provided from an upstream end. A blower rotating mechanism 259 such as an inverter or the like is connected to the blower 257 and the blower 257 is configured to be rotated by the blower rotating mechanism 259.

A cooling gas exhaust system configured to exhaust the atmosphere in the space 260 between the insulating member 210 and the reaction tube 203 mainly includes the cooling gas exhaust tube 253, the radiator 255, the blower 257 and the exhaust mechanism 258. Also, the shutter 254 or the shutter 256 may be considered as included in the cooling gas exhaust system. Also, a reaction tube the cooling unit mainly includes the above-described cooling gas supply system and cooling gas exhaust system.

(Second Heating Unit)

For example, when hydrogen peroxide is used as a reactant and a hydrogen peroxide gas, in which a hydrogen peroxide solution, which is hydrogen peroxide in a liquid state, is vaporized or misted, is used as a processing gas, the hydrogen peroxide gas may be cooled and re-liquefied at a lower temperature than an evaporation point of the hydrogen peroxide in the reaction tube 203.

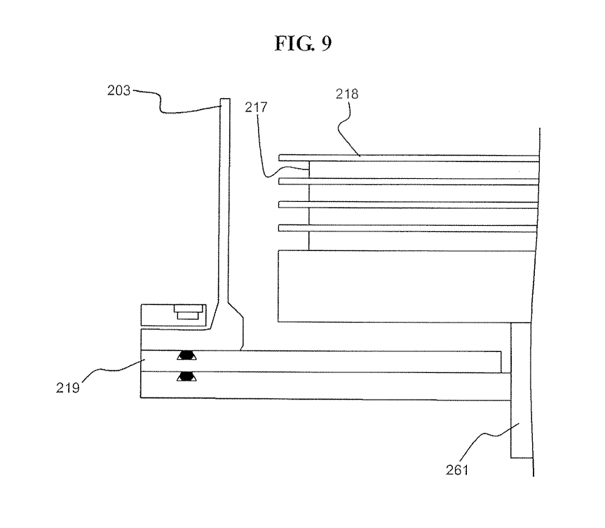

The re-liquefaction of the hydrogen peroxide gas may often occur in regions other than a region heated by the first heating unit 207 in the reaction tube 203. Since the first heating unit 207 is provided to heat the wafers 200 in the reaction tube 203 as described above, a region in which the wafers 200 in the reaction tube 203 are accommodated is heated by the first heating unit 207. However, regions other than the region in which the wafers 200 in the reaction tube 203 are accommodated are difficult for the first heating unit 207 to heat. As a result, the regions other than the region in the reaction tube 203 heated by the first heating unit 207 may be a low-temperature region, and the hydrogen peroxide gas may be cooled and re-liquefied while passing through the low-temperature region. As will be illustrated in FIG. 9, a heating unit configured to heat the processing gas flowing in the reaction tube 203 in a downstream region in the reaction tube 203 [a region in which the insulator 218 in the reaction tube 203 is accommodated, that is, a lower portion of the reaction tube 203] is not provided in a treatment furnace 202 included in a conventional substrate processing apparatus. Thus, the processing gas may be re-liquefied in a downstream region (the lower portion of the reaction tube 203) in the reaction tube 203.

A liquid generated by the re-liquefaction of the hydrogen peroxide gas (hereinafter, simply referred to as “liquid”) may accumulate on a bottom [an upper surface of the seal cap 219] in the reaction tube 203. Thus, the re-liquefied hydrogen peroxide reacts with the seal cap 219 and the seal cap 219 may be damaged.

Also, in order to unload the boat 217 to the outside of the reaction tube 203, in the case in which the seal cap 219 is lowered and the furnace [a lower end opening of the reaction tube 203] is open, when liquid is accumulated on the seal cap 219, the liquid on the seal cap 219 may flow to the outside of the reaction tube 203 through the furnace. Thus, members in the vicinity of the furnace of the treatment furnace 202 may be damaged and also an operator or the like cannot safely enter and exit the vicinity of the treatment furnace 202.

The hydrogen peroxide solution is prepared by dissolving hydrogen peroxide in water, using hydrogen peroxide (H₂O₂) as a raw material (reactant) which is solid or liquid at room temperature and water (H₂O) as a solvent. That is, the hydrogen peroxide solution is made of hydrogen peroxide and water which have different evaporation points. Thus, the liquid generated by the re-liquefaction of the hydrogen peroxide gas may have a greater concentration of hydrogen peroxide than the concentration of the hydrogen peroxide solution when being supplied into the reaction tube 203.

The liquid generated by the re-liquefaction of the hydrogen peroxide gas is further vaporized in the reaction tube 203, and thus a regasification gas may be generated. As described above, since the evaporation points of hydrogen peroxide and water are different, the regasification gas may have the greater concentration of hydrogen peroxide than the concentration of the hydrogen peroxide gas when being supplied into the wafer 200.

Therefore, the concentration of the hydrogen peroxide gas may be non-uniform in the reaction tube 203 in which the regasification gas is generated. As a result, the substrate processing is non-uniformly performed between the plurality of wafers 200 in the reaction tube 203, and thus a deviation is likely to occur in characteristics of the substrate processing. Also, substrate processing between lots may be non-uniform.

Also, the concentration of hydrogen peroxide may be increased by repeating the re-liquefaction and the regasification of the hydrogen peroxide. As a result, a danger of explosion or combustion due to the high-concentration of the hydrogen peroxide solution may be increased.

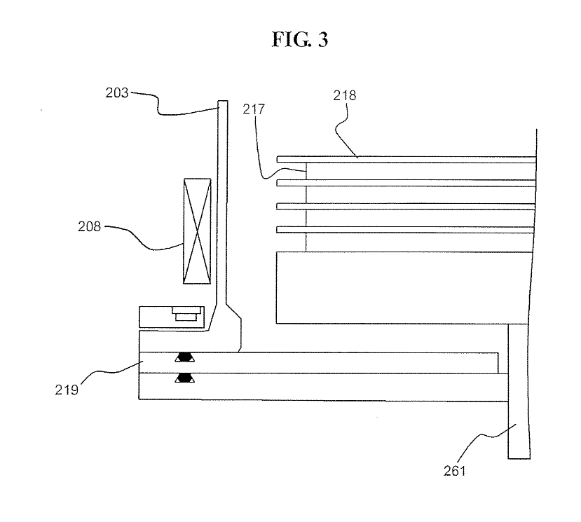

Thus, as illustrated in FIGS. 1, 2 and 3, a second heating unit 208 is provided to heat the regions other than the region heated by the first heating unit 207. That is, the second heating unit 208 is provided in an outside (outer circumference) of the lower portion of the reaction tube 203 to concentrically surround the side wall of the reaction tube 203.

The second heating unit 208 is configured to heat the hydrogen peroxide gas flowing from the upper portion (upstream) of the reaction tube 203 to the lower portion (downstream) thereof toward the exhaust unit in the downstream region in the reaction tube 203 [i.e., the region in which the insulator 218 in the reaction tube 203 is accommodated, the lower portion of the reaction tube 203]. Also, the second heating unit 208 is configured to heat the seal cap 219 configured to seal the lower end opening of the reaction tube 203, or the lower portion of the reaction tube 203 and a member that forms the lower portion of the reaction tube 203 such as the insulator 218 provided in the bottom in the reaction tube 203. In other words, when the boat 217 is loaded into the processing chamber 201, the second heating unit 208 is disposed to be located at a lower level than the bottom plate 217b.

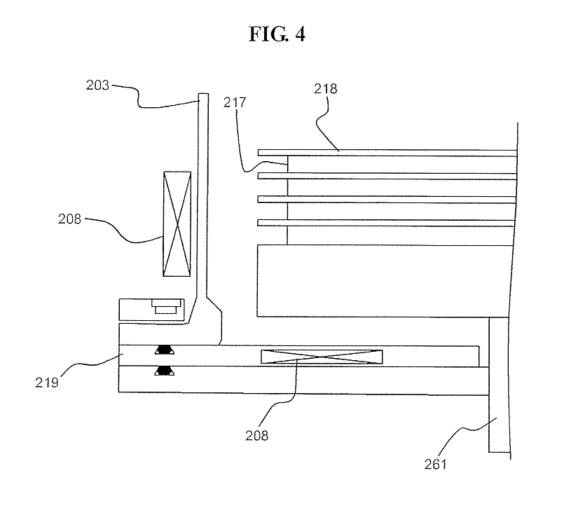

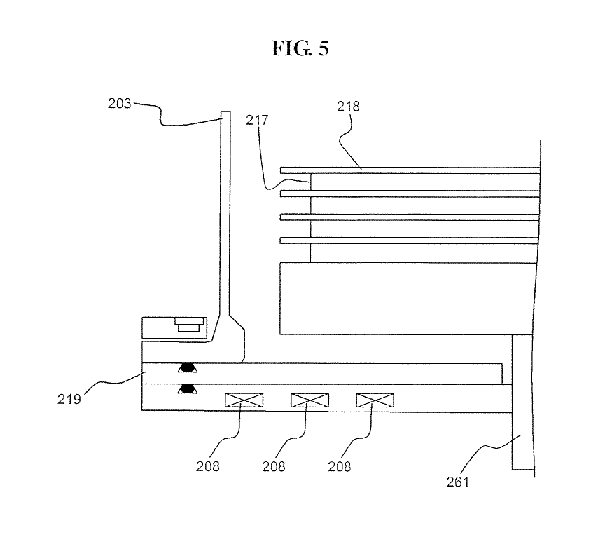

Also, the second heating unit 208 may be provided by being embedded inside a member [the seal cap 219] configured to seal the lower end opening of the reaction tube 203 as illustrated in FIG. 4. Also, the second heating unit 208 may be provided on a lower outside of the seal cap 219 as illustrated in FIG. 5. Also, as illustrated in FIG. 4, two second heating units 208 may be provided on the outside of the lower portion of the reaction tube 203 and the inside of the seal cap 219, and three second heating units 208 or more may be provided.

The controller 121 to be described below is electrically connected to the second heating unit 208. The controller 121 is configured to control a power supplied to the second heating unit 208 at a predetermined timing such that the second heating unit 208 becomes a temperature (e.g., a range from 150° C. to 170° C.) at which the liquefaction of the processing gas (a hydrogen peroxide gas) in the reaction tube 203 may be suppressed.

(Heat Absorbing Unit)

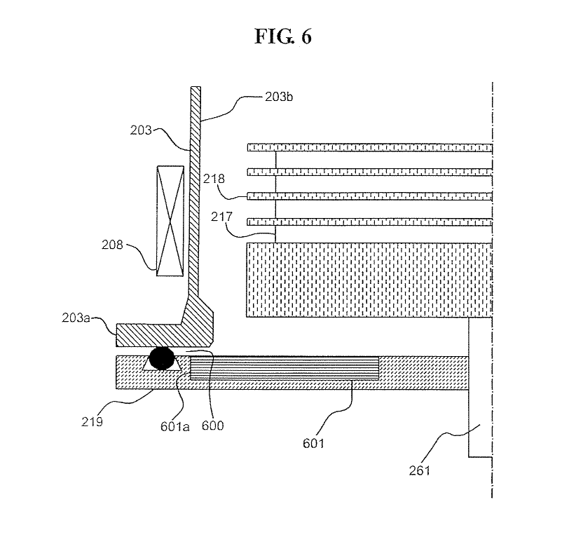

The inventors confirmed that, as illustrated in FIG. 6, the processing gas is liquefied and the liquid accumulates in a gap 600 between a lower end portion 203a of the reaction tube 203 and the seal cap 219. The gap 600 is a clearance formed by an O ring (sealing unit) provided between the lower end portion 203a and the seal cap 219. The liquefaction of the processing gas occurs by cooling the processing gas by the cooled O ring (sealing unit) or a member in the vicinity of the cooled O ring. Also, when the liquefied processing gas is accumulated, processing uniformity of the wafer is degraded and the generation of particles (impurities) occurs. Also, a portion near the gap 600 is cooled and forms a structure in which the liquid easily accumulates. Also, when the liquid accumulates, a degree of vacuum in the processing chamber 201 is reduced.

Thus, the inventors provided a heat absorbing unit 601 at a position corresponding to the lower end portion 203a of the seal cap 219. The heat absorbing unit 601 is configured to be heated by the above-described second heating unit 208. As the heat absorbing unit 601 is provided in this manner, the portion near the gap 600 is heated and the liquefaction by the decrease in the temperature of the processing gas in the gap 600 may be suppressed.

Also, a side surface of the outer circumference of the heat absorbing unit 601, that is, an outer perimeter surface 601a is provided outer than an inner circumference of the lower end portion 203a of the reaction tube 203, and is preferably provided inside the O ring (sealing unit) as illustrated in FIG. 6. Also, the outer perimeter surface 601a may be provided outer than an inner sidewall surface 203b of the reaction tube 203. Also, the outer perimeter surface 601a may be provided more outward than the inner sidewall surface 203b of the reaction tube 203 and inside the O ring. When a heat resistance temperature of the O ring is high, it may be configured to heat to an outside of the O ring.

As the heat absorbing unit 601, for example, a non-metallic material having good thermal conductivity, such as silicon carbide (SiC), aluminum oxide (AlO), aluminum nitride (AlN), silicon nitride (SiN) and zirconium oxide (ZrO), may be used. Specifically, a non-metallic material having a thermal conductivity of 10 W/mK or more may be used. Also, a material which easily absorbs heat rays emitted from the second heating unit 208 is preferable. Also, a material which is easily heated by infrared is preferable. As such a material, for example, SiC is used. In such a configuration of a material having excellent thermal conductivity, the gap 600 corresponding to an entire region of the lower end portion 203a of the reaction tube 203 may be heated. Also, in such a configuration of a material which is easily heated by infrared, when a substrate processing process to be described below is repeated, the heat absorbing unit 601 cooled between the substrate processing processes (from boat unloading to boat loading) may be efficiently heated. That is, a temperature regulation time of the heat absorbing unit 601 can be reduced, and thus the throughput of the substrate processing can be improved.

The temperature of the heat absorbing unit 601 may be directly measured by providing a temperature sensor (not illustrated) in the heat absorbing unit 601, and indirectly measured by measuring the temperature of the seal cap 219 or the O ring. Also, the temperature of the heat absorbing unit 601 may be measured by the heating time of the second heating unit 208. Also, when the time of the substrate processing is increased and the temperature of the heat absorbing unit 601 is greater than an allowed temperature, the controller to be described below may control the second heating unit 208 based on the measured temperature.

(Control Unit)

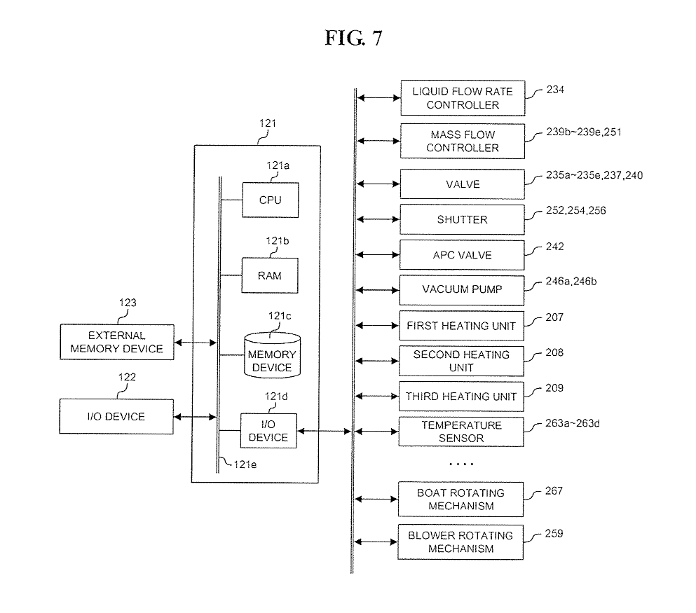

As illustrated in FIG. 7, the controller 121 serving as a control unit (control device) is configured as a computer that includes a central processing unit (CPU) 121a, a random access memory (RAM) 121b, a memory device 121c and an input and output (I/O) port 121d. The RAM 121b, the memory device 121c and the I/O port 121d are configured to exchange data with the CPU 121a through an internal bus 121e. An I/O device 122 configured as, for example, a touch panel, is connected to the controller 121.

The memory device 121c is configured as, for example, a flash memory, a hard disk drive (HDD) or the like. A control program controlling operations of the substrate processing apparatus, a process recipe describing sequences or conditions of substrate processing to be described below and the like are readably stored in the memory device 121c. Also, the process recipe, which is a combination of sequences, causes the controller 121 to execute each sequence in the substrate processing process to be described below in order to obtain a predetermined result and functions as a program. Hereinafter, such a process recipe, a control program and the like are collectively and simply referred to as a “program.” Also, when the term “program” is used in this specification, it may refer to either or both of the process recipe and the control program. Also, the RAM 121b is configured as a memory area (work area) in which a program, data and the like read by the CPU 121a are temporarily stored.

The I/O port 121d is connected to the LMFC 234, the MFCs 239b, 239c, 239d, 239e and 251, the valves 235a, 235b, 235c, 235d, 235e, 237 and 240, the shutters 252, 254 and 256, the APC valve 242, the first heating unit 207, the second heating unit 208, the third heating unit 209, the blower rotating mechanism 259, the first temperature sensor 263a, the second temperature sensor 263b, the third temperature sensor 263c, the fourth temperature sensor 263d, the boat rotating mechanism 267 and the like.

The CPU 121a is configured to read and execute the control program from the memory device 121c and read the process recipe from the memory device 121c according to an input of a manipulating command from the I/O device 122. To comply with the content of the read process recipe, the CPU 121a is configured to control a flow rate regulating operation of the liquid source by the LMFC 234, a flow rate regulating operation of various types of gases by the MFCs 239b, 239c, 239d, 239e and 251, an opening and closing operation of the valves 235a, 235b, 235c, 235d, 235e, 237 and 240, a shut-off operation of the shutters 252, 254 and 256, a degree of opening regulating operation of the APC valve 242, a temperature regulating operation by the first heating unit 207 based on the first temperature sensor 263a, the second temperature sensor 263b, the third temperature sensor 263c and the fourth temperature sensor 263d, a temperature regulating operation by the second heating unit 208 and the third heating unit 209 based on the temperature sensor, starting and stopping of the vacuum pumps 246a and 246b, a rotation and rotational speed regulating operation of the blower rotating mechanism 259, a rotation and rotational speed regulating operation of the boat rotating mechanism 267 and the like.

Also, the controller 121 is not limited to being configured as a dedicated computer but may be configured as a general-purpose computer. For example, the controller 121 according to the present embodiment may be configured by preparing an external memory device 123 [e.g., a magnetic tape, a magnetic disk such as a flexible disk and a hard disk, an optical disc such as a compact disc (CD) and a digital video disc (DVD), a magneto-optical disc such as a magneto-optical (MO) drive and a semiconductor memory such as a Universal Serial Bus (USB) memory and a memory card] recording the above program and then installing the program in the general-purpose computer using the external memory device 123. Also, a method of supplying the program to the computer is not limited to using the external memory device 123. For example, a communication line such as the Internet or an exclusive line may be used to supply the program without using the external memory device 123. Also, the memory device 121c or the external memory device 123 is configured as a non-transitory computer-readable recording medium. Hereinafter, these are also collectively and simply referred to as a recording medium. Also, when the term “recording medium” is used in this specification, it refers to either or both of the memory device 121c and the external memory device 123.

(2) Substrate Processing Process

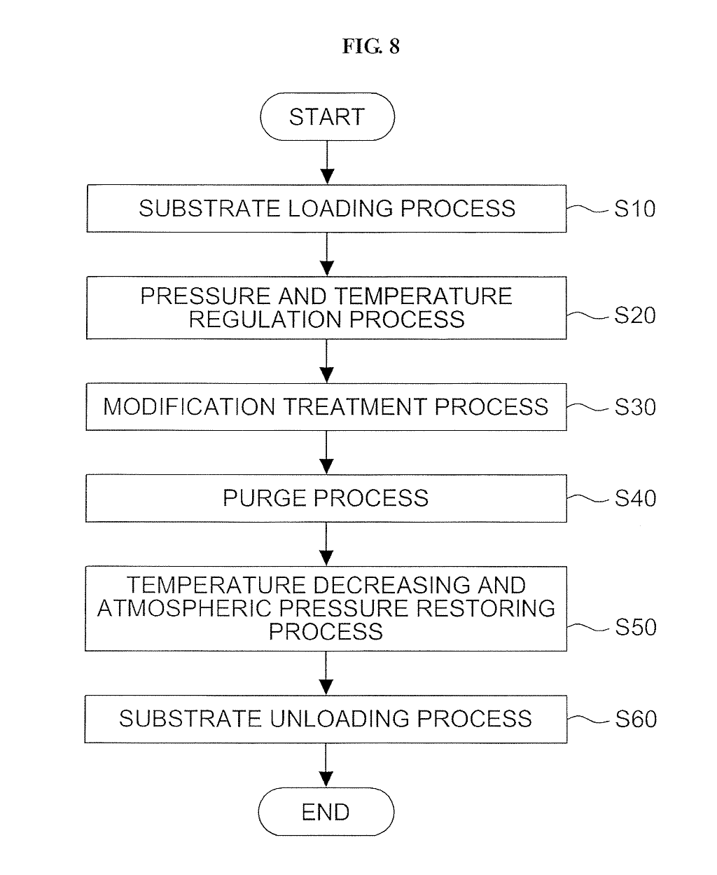

Then, a substrate processing process performed as a process among manufacturing processes of a semiconductor apparatus according to the present embodiment will be described with reference to FIG. 8. The process is performed by the above-described substrate processing apparatus. In the present embodiment, as an example of the substrate processing process, the case in which a process (a modification treatment process), in which a Si film formed on the wafer 200 serving as the substrate is modified to a SiO film using hydrogen peroxide serving as a reactant, is performed will be described. Also, in the following description, operations of respective units constituting the substrate processing apparatus are controlled by the controller 121.

Here, as the wafer 200, a substrate having a fine structure of an irregular structure, in which a Si-containing film is formed in a recessed region (groove), is used. The Si-containing film is, for example, a film including a silazane bond (Si—N bonding) formed using polysilazane (SiH₂NH). The Si-containing film includes, for example, hexamethyldisilazane (HMDS), hexamethylcyclotrisiloxane (HMCTS), polycarbosilane, polyorganosilazane and the like other than the polysilazane. Also, a Si-containing film formed using a chemical vapor deposition (CVD) method may be used. In the CVD method, for example, monosilane (SiH₄) gas, trisilylamine (TSA) gas or the like is used. Also, the substrate having the fine structure refers to a substrate having a high aspect ratio such as a large groove (a recessed region) in a vertical direction or a small groove (a recessed region), for example, of about 50 nm in a horizontal direction.

Since the hydrogen peroxide solution has a higher activation energy compared to water vapor (water, H₂O) and the number of oxygen atoms contained in a single molecule is large, oxidizing power is high. Thus, when the hydrogen peroxide gas is used as the processing gas, the oxygen atoms may reach a deep portion (a bottom of the groove) of the film formed in the groove of the wafer 200. Therefore, a degree of the modification treatment may be more uniform between the surface and the deep portion of the film formed on the wafer 200. That is, the substrate processing may be more uniformly performed between the surface and the deep portion of the film formed on the wafer 200, and thus a dielectric constant of the wafer 200 after the modification treatment may be uniform. Also, the modification treatment process may be performed at a low temperature in a range of 40° C. to 100° C., degradation in the performance of circuits formed on the wafer 200 may be suppressed. Also, in the present embodiment, a gas in which hydrogen peroxide serving as the reactant is vaporized or misted (i.e., hydrogen peroxide in a gaseous state) is referred to as a hydrogen peroxide gas and hydrogen peroxide in a liquid state is referred to as a hydrogen peroxide solution.

[Substrate Loading Process (S10)]

First, a predetermined number of wafers 200 are loaded on the boat 217 (wafer charging). The boat 217 holding the plurality of wafers 200 is lifted by the boat elevator to be loaded into the reaction tube 203 [in the processing chamber 201] (boat loading). In this state, the furnace which is the opening of the treatment furnace 202 is sealed by the seal cap 219.

[Pressure and Temperature Regulating Process (S20)]

Vacuum-exhausting is performed by any one of the vacuum pump 246a and the vacuum pump 246b such that a pressure in the reaction tube 203 reaches a desired pressure (a degree of vacuum). In this case, the pressure in the reaction tube 203 is measured by the pressure sensor and an opening of the APC valve 242 or opening and closing of the valve 240 is feedback-controlled based on the measured pressure (pressure regulating).

The wafer 200 accommodated in the reaction tube 203 is heated to reach a desired temperature, for example, in a range 40° C. to 400° C. and preferably in a range of 100° C. to 350° C. by the first heating unit 207. In this case, the power supplied to the first heater unit 207a, the second heater unit 207b, the third heater unit 207c and the fourth heater unit 207d included in the first heating unit 207 is feedback-controlled based on temperature information detected by the first temperature sensor 263a, the second temperature sensor 263b, the third temperature sensor 263c and the fourth temperature sensor 263d such that the temperature of the wafer 200 in the reaction tube 203 becomes a desired temperature (temperature regulating). In this case, set temperatures of the first heater unit 207a, the second heater unit 207b, the third heater unit 207c and the fourth heater unit 207d are controlled to be the same temperature. Also, the second heating unit 208 is controlled to have a temperature at which the hydrogen peroxide gas is not re-liquefied in the reaction tube 203 [specifically, below the reaction tube 203]. Also, specifically, the heat absorbing unit 601 is heated by the second heating unit 208 to have the temperature at which the hydrogen peroxide gas is not re-liquefied in the gap 600 (e.g., in a range of 100° C. to 200° C.). The heating of the heat absorbing unit 601 is continued until at least the modification treatment process is completed. Preferably, it is continued until the temperature decreasing and atmospheric pressure restoring process is completed. Also, the heating may be continued in any range allowed as long as it can heat the other device or substrate in the substrate unloading process.

Also, the boat rotating mechanism 267 operates while the wafer 200 is heated, and begins to rotate the boat 217. In this case, the rotational speed of the boat 217 is controlled by the controller 121. Also, the boat 217 always rotates until at least the modification treatment process (S30) to be described below is completed.

[Modification Treatment Process (S30)]

When the wafer 200 is heated to reach a desired temperature and the boat 217 reaches a desired rotational speed, a supply of the hydrogen peroxide solution into the reaction tube 203 through the reactant supply pipe 232a is started. That is, the valves 235c, 235d and 235e are closed and the valve 235b is open. Next, the pressurized gas is supplied from the pressurized gas supply source 238b into the reactant supply tank 233 while a flow rate is controlled by the MFC 239b. Also, while the valve 235a and the valve 237 are open and the flow rate of hydrogen peroxide accumulated in the reactant supply tank 233 is controlled by the LMFC 234, the pressurized gas is supplied into the reaction tube 203 through the reactant supply pipe 232a via the separator 236, the supply nozzle 230 and the supply holes 231. As the pressurized gas, an inert gas such as a nitrogen (N₂) gas, or rare gases such as He gas, Ne gas and Ar gas may be used.

Here, the reason that the hydrogen peroxide solution rather than the hydrogen peroxide gas passes through the supply nozzle 230 will be described. When the hydrogen peroxide gas passes through the supply nozzle 230, deviation in the concentration of the hydrogen peroxide gas occurs by a thermal condition of the supply nozzle 230. Thus, it is difficult to perform the substrate processing to have good reproducibility. Also, when a hydrogen peroxide gas having a high hydrogen peroxide concentration passes through an inside of the supply nozzle 230, the supply nozzle 230 is considered to corrode. Thus, a foreign material caused by the corrosion may possibly adversely affect the substrate processing such as a film processing. Thus, in the present embodiment, the hydrogen peroxide solution passes through the supply nozzle 230.

The hydrogen peroxide solution supplied into the reaction tube 203 through the supply nozzle 230 contacts the top plate 217c of the boat 217 heated by the third heating unit 209, and thus the hydrogen peroxide gas (i.e., a hydrogen peroxide solution gas) serving as the processing gas is generated.

When the hydrogen peroxide gas is supplied onto the wafer 200 and an oxidation reaction of the hydrogen peroxide gas with a surface of the wafer 200 is performed, the Si film formed on the wafer 200 is modified to the SiO film.

While the hydrogen peroxide solution is supplied into the reaction tube 203, exhausting is performed using the vacuum pump 246b and the liquid recovery tank 247. That is, the APC valve 242 is closed, the valve 240 is open, and an exhaust gas exhausted from the inside of the reaction tube 203 passes through the inside of the separator 244 through the second exhaust tube 243 from the first exhaust tube 241. After the exhaust gas is divided into liquid containing hydrogen peroxide and gas not containing hydrogen peroxide by the separator 244, the gas is exhausted from the vacuum pump 246b and the liquid is recovered in the liquid recovery tank 247.

Also, when the hydrogen peroxide solution is supplied into the reaction tube 203, the valve 240 and the APC valve 242 may be closed and the pressure of the inside of the reaction tube 203 may be increased. Thus, the hydrogen peroxide solution atmosphere in the reaction tube 203 may be uniformly maintained.

After a predetermined time has elapsed, the valves 235a, 235b and 237 are closed to stop the supply of the hydrogen peroxide solution into the reaction tube 203.

[Purge Process (S40)]

After the modification treatment process (S30) is completed, the APC valve 242 is closed, the valve 240 is open, vacuum-exhausting in the reaction tube 203 is performed, and the hydrogen peroxide gas remaining in the reaction tube 203 is exhausted. That is, the valve 235a is closed, the valves 235c and 237 are open, and N₂ gas (inert gas) serving as a purge gas is supplied into the reaction tube 203 through the inert gas supply pipe 232c via the supply nozzle 230 while a flow rate thereof is controlled by the MFC 239c. As the purge gas, an inert gas such as a nitrogen (N₂) gas, or rare gases such as He gas, Ne gas and Ar gas may be used. Thus, a discharge of the residual gas in the reaction tube 203 can be facilitated. Also, when the N₂ gas passes through the inside of the supply nozzle 230, it is possible to extrude and remove the hydrogen peroxide solution (hydrogen peroxide in a liquid state) remaining in the supply nozzle 230. In this case, the opening of the APC valve 242 and the opening and closing of the valve 240 are regulated and the hydrogen peroxide remaining in the supply nozzle 230 may be exhausted through the vacuum pump 246a.

[Temperature Decreasing and Atmospheric Pressure Restoring Process (S50)]

After the purge process (S40) is completed, at least one of the valve 240 and the APC valve 242 is open, and the temperature of the wafer 200 is decreased to a predetermined temperature (e.g., about room temperature) while the pressure in the reaction tube 203 is returned. Specifically, in a state in which the valve 235c is open, the pressure in the reaction tube 203 is increased to an atmospheric pressure while the N₂ gas serving as the inert gas is supplied into the reaction tube 203. The temperature of the wafer 200 is decreased by controlling the power supplied to the first heating unit 207 and the third heating unit 209.

Also, the temperature of the heat absorbing unit 601 is decreased by controlling the second heating unit 208. Specifically, the power supplied to the second heating unit 208 is stopped and the temperature of the heat absorbing unit 601 is decreased.

In a state in which the blower 257 operates while the temperature of the wafer 200 is decreased, the shutters 252, 254 and 256 are open, the cooling gas may be exhausted through the cooling gas exhaust tube 253 by supplying the cooling gas into the space 260 between the reaction tube 203 and the insulating member 210 while a flow rate thereof through the cooling gas supply pipe 249 is controlled by the MFC 251. As the cooling gas, in addition to N₂ gas, rare gases such as He gas, Ne gas and Ar gas, or air may be used alone or in a combination thereof. Thus, the inside of the space 260 may be rapidly cooled and the reaction tube 203 and the first heating unit 207 which are provided in the space 260 may be cooled in a short time. Also, the temperature of the wafer 200 in the reaction tube 203 may be further decreased in a short time.

Also, in a state in which the shutters 254 and 256 are closed, the N₂ gas is supplied into the space 260 through the cooling gas supply pipe 249, the inside of the space 260 is filled with the cooling gas to be cooled, and then in a state in which the blower 257 operates, the shutters 254 and 256 are open, the cooling gas in the space 260 may be exhausted through the cooling gas exhaust tube 253.

[Substrate Unloading Process (S60)]

Then, the seal cap 219 is lowered by the boat elevator, the lower end of the reaction tube 203 is open, and at the same time the processed wafer 200 is unloaded (boat unloading) to the outside of the reaction tube 203 [processing chamber 201] from the lower end of the reaction tube 203 while being held on the boat 217. Then, the processed wafer 200 is extracted from the boat 217 (wafer discharging), and the substrate processing process according to the present embodiment is completed.

As described above, when the inside of the reaction tube 203 is heated by the first heating unit 207 and the second heating unit 208, the low-temperature region in the reaction tube 203 is reduced, and thus a cooling of the hydrogen peroxide gas to a temperature lower than an evaporation point in the reaction tube 203 can be suppressed. That is, re-liquefaction of the hydrogen peroxide gas in the reaction tube 203 can be suppressed.

Therefore, an accumulation of the liquid generated by the re-liquefaction of the hydrogen peroxide gas, for example, on the seal cap 219 can be reduced. Thus, damage to the seal cap 219 by reaction with the hydrogen peroxide in the liquid can be reduced. Also, in order to unload the boat 217 to the outside of the reaction tube 203, when the seal cap 219 is lowered, the furnace [the lower end opening of the reaction tube 203] is open, the liquid accumulated on the seal cap 219 flowing to the outside of the reaction tube 203 through the furnace can be reduced. As a result, damage to peripheral members of the treatment furnace 202 by the hydrogen peroxide can be reduced. Also, the operators may more safely enter and exit in the vicinity of the treatment furnace 202.

Also, the liquid generated by the re-liquefaction of the hydrogen peroxide gas is further evaporated in the reaction tube 203, and thus generation of a re-evaporated gas having the hydrogen peroxide of high concentration can be reduced. Therefore, the concentration of the hydrogen peroxide solution in the reaction tube 203 can be made uniform, and the substrate processing between the plurality of wafers 200 or between lots in the reaction tube 203 can be more uniformly performed.

Also, since the hydrogen peroxide solution of the high concentration is reduced, a concern about explosion or combustion by the high concentration of the hydrogen peroxide solution further decreases.

Also, as illustrated in FIG. 1, the sub-heater 211 may be provided upstream from at least the APC valve 242 of the first exhaust tube 241 serving as the heating unit configured to heat the first exhaust tube 241. When the first exhaust tube 241 is heated by heating the sub-heater 211, the low-temperature region in the reaction tube 203 is reduced, and thus re-liquefaction of the hydrogen peroxide gas in the reaction tube 203 can be further suppressed. Also, the sub-heater 211 may be included in the above-described second heating unit 208.

### Other Embodiments of the Present Invention

Embodiments of the present invention have been specifically described above. The present invention is not limited to the above-described embodiments, but may be variously changed without departing from the scope of the invention.

In the above-described embodiments, a case in which the hydrogen peroxide gas is used as the processing gas has been described, but is not limited thereto. That is, the processing gas may refer to a gas generated by vaporizing a solution (a reactant in a liquid state) in which a solid or liquid raw material (a reactant) at room temperature is dissolved in a solvent. Also, when an evaporation point of the raw material (a reactant) is different from an evaporation point of the solvent, it is easy to obtain effects of the above-described embodiments. Also, when the vaporized gas serving as the processing gas is re-liquefied, it is not limited to the higher concentration of the raw material, and it may be lowered the concentration of the raw material. Such a processing gas may make a concentration of the processing gas in the reaction vessel 203 uniform.

Also, the use of the hydrogen peroxide gas serving as an oxidizing agent is not limiting, and water (H₂O) gas vaporized by heating a gas (a hydrogen-containing gas) containing a hydrogen atom (H) such as hydrogen (H₂) gas and a gas (oxygen-containing gas) containing an oxygen atom (O) such as oxygen (O₂) gas may be used. Also, water vapor generated by heating water (H₂O) may be used. That is, the valves 235a, 235b and 237 are closed, the valves 235d and 235e are open, and H₂ gas and O₂ gas may be supplied into the reaction tube 203 through the first gas supply pipe 232d and the second gas supply pipe 232e while the flow rate thereof is controlled by the MFCs 239d and 239e. The H₂ gas and the O₂ gas supplied in the reaction tube 203 are brought in contact with the top plate 217c of the boat 217 heated by the third heating unit 209 to be vaporized and to supply to the wafer 200 and thus the Si film formed on the wafer 200 may be modified to the SiO film. Also, as the oxygen-containing gas, in addition to the O₂ gas, for example, ozone (O₃) gas or water vapor (H₂O) may be used. However, since hydrogen peroxide has high activation energy and the number of oxygen atoms contained in one molecule is large, oxidizing power is high compared to water vapor (water (H₂O)). Therefore, when hydrogen peroxide gas is used, it is advantageous in that an oxygen atom (O) can reach a deep portion of a film (bottom of the groove) formed in the groove of the wafer 200. Also, when hydrogen peroxide is used, the modification treatment process may be performed at a low temperature in a range of 40° C. to 150° C., degradation in the performance of a circuit formed on the wafer 200, specifically, a circuit using a weak material (e.g., aluminum) in high temperature treatment may be suppressed.

Also, when a gas (a vaporized gas) generated by vaporizing water (H₂O) is used as an oxidizing agent, a gas (a processing gas) supplied onto the wafer 200 may include an H₂O molecule group or a cluster to which several molecules are combined. Also, when water (H₂O) is converted from a liquid state to a gaseous state, water (H₂O) may be divided to the H₂O molecule group or to the cluster to which several molecules are combined. Also, the multiple clusters may be collected to be fog (mist).

Also, when a hydrogen peroxide solution (H₂O₂) is used as an oxidizing agent in the same manner, a gas supplied onto the wafer 200 may include H₂O₂, molecule group or a cluster to which several molecules are combined. Also, when it is converted from the hydrogen peroxide solution (H₂O₂) to the hydrogen peroxide gas, it may be divided into the H₂O₂ molecule group or into the cluster state to which several molecules are combined. Also, the multiple clusters may be collected to be fog (mist).

Also, in the above-described embodiments, the hydrogen peroxide gas serving as the processing gas has been generated in the reaction tube 203, but is not limited thereto. That is, for example, the hydrogen peroxide gas pre-vaporized outside the reaction tube 203 may be supplied into the reaction tube 203 through the supply nozzle 230. Thus, atmosphere of the hydrogen peroxide gas in the reaction tube 203 may be made more uniform. However, in this case, when the hydrogen peroxide gas passes through the supply nozzle 230, the hydrogen peroxide gas may be re-liquefied in the supply nozzle 230. Specifically, the hydrogen peroxide gas often re-liquefies and accumulates on a curved or joint portion of the supply nozzle 230. As a result, the inside of the supply nozzle 230 may be damaged by liquid generated by the re-liquefaction in the supply nozzle 230.

In the above-described treatment furnace 202, as the temperature sensor configured to detect each temperature of the first heater unit 207a, the second heater unit 207b, the third heater unit 207c and the fourth heater unit 207d included in the first heating unit 207 in addition to the reaction tube 203, a first external temperature sensor 264a, a second external temperature sensor 264b, a third external temperature sensor 264c and a fourth external temperature sensor 264d (see FIG. 2) such as thermocouple may be provided. The first external temperature sensor 264a, the second external temperature sensor 264b, the third external temperature sensor 264c and the fourth external temperature sensor 264d are each connected to the controller 121. Thus, whether each of the first heater unit 207a, the second heater unit 207b, the third heater unit 207c and the fourth heater unit 207d is heated to a predetermined temperature or not may be determined based on temperature information detected by the first external temperature sensor 264a, the second external temperature sensor 264b, the third external temperature sensor 264c and the fourth external temperature sensor 264d.

Also, for example, in the above-described embodiments, between the purge process (S40) and the temperature decreasing and atmospheric pressure restoring process (S50), the wafer 200 is heated to a high temperature, for example, in a range of 800° C. to 1,000° C. and a thermocouple annealing (a heat treatment) process and the like may be performed. When the annealing process is performed, as described above, in the temperature decreasing and atmospheric pressure restoring process (S50), while the temperature of the wafer 200 is decreased, the shutter 252 is open, and N₂ gas serving as a cooling gas may be supplied into the space 260 between the reaction tube 203 and the insulating member 210 through the cooling gas supply pipe 249. Thus, the reaction tube 203 and the first heating unit 207 which are provided in the space 260 may be cooled in a short time. As a result, the start time of the next modification treatment process (S30) is advanced, and thus throughput can be improved.

In the above-described embodiments, the substrate processing apparatus including a vertical processing furnace has been described, but is not limited thereto. A substrate processing apparatus that includes, for example, a furnace of a single wafer type, a hot wall type or a cold wall type, or a substrate processing apparatus configured to process the wafer 200 by exciting the processing gas may be preferably applied.

According to the substrate processing apparatus, the method of manufacturing the semiconductor device and the furnace lid of the present invention, re-liquefaction of a processing gas in a reaction tube can be suppressed and the processing gas in the reaction tube can be maintained in a gaseous state.

### Preferred Embodiments of the Present Invention

Hereinafter, preferred embodiments according to the present invention are supplementarily noted.

<Supplementary Note 1>

According to an aspect of the present invention, there is provided a substrate processing apparatus including:

a reaction tube where a substrate is processed;

a supply unit configured to supply a reactant to the substrate;

an exhaust unit configured to exhaust an inside atmosphere of the reaction tube;

a first heating unit configured to heat the substrate in the reaction tube;

a second heating unit configured to heat a downstream portion of the reactant in gaseous state flowing in the reaction tube from the supply unit toward the exhaust unit; and

a furnace lid configured to cover a lower end portion of the reaction tube, wherein the furnace lid includes a heat absorbing unit facing a lower surface of the lower end portion and being heated by the second heating unit.

<Supplementary Note 2>

According to another aspect of the present invention, there is provided a substrate processing apparatus including:

a reaction tube where a substrate is processed;

a supply unit configured to supply a reactant to the substrate;

an exhaust unit configured to exhaust an inside atmosphere of the reaction tube;

a first heating unit configured to heat the substrate in the reaction tube;

a second heating unit configured to heat a region other than a region heated by the first heating unit; and

a furnace lid configured to cover a lower end portion of the reaction tube, wherein the furnace lid includes a heat absorbing unit facing a lower surface of the lower end portion and being heated by the second heating unit.

<Supplementary Note 3>

In the substrate processing apparatus of Supplementary note 1, preferably, further includes a control unit configured to control the first heating unit to maintain a temperature of the substrate at a predetermined processing temperature, and control the second heating unit to maintain the reactant in gaseous state in the reaction tube.

<Supplementary Note 4>

In the substrate processing apparatus of Supplementary note 1, preferably, further includes a control unit configured to control the second heating unit to heat the heat absorbing unit such that the reactant in a gap between the reaction tube and the furnace lid is maintained in gaseous state

<Supplementary Note 5>

In the substrate processing apparatus of Supplementary note 1, preferably, an outer perimeter surface of the heat absorbing unit is disposed outer than an inner circumference surface of the lower end portion

<Supplementary Note 6>

In the substrate processing apparatus of Supplementary note 1, preferably, an outer perimeter surface of the heat absorbing unit is disposed outer than an inner sidewall surface of the reaction tube.

<Supplementary Note 7>

In the substrate processing apparatus of Supplementary note 6, preferably, the heat absorbing unit is disposed inner than a sealing unit disposed in a gap between the reaction tube and the furnace lid.

<Supplementary Note 8>

In the substrate processing apparatus of Supplementary note 1, preferably, the second heating unit is disposed outer than the lower end portion.

<Supplementary Note 9>

In the substrate processing apparatus of Supplementary note 1, preferably, the second heating unit is disposed on a lower outside of a member configured to seal a lower end opening of the reaction tube.

<Supplementary Note 10>

In the substrate processing apparatus of Supplementary note 1, preferably, the reactant is solid or liquid at room temperature, and a solution in which the reactant is dissolved in a solvent has a characteristic to be vaporized.

<Supplementary Note 11>

In the substrate processing apparatus of Supplementary note 10, preferably, an evaporation point of the reactant is different from that of the solvent.

<Supplementary Note 12>

In the substrate processing apparatus of Supplementary note 1, preferably, the reactant is vaporized in the reaction tube to be in a gaseous state after being supplied into the reaction tube in a liquid state.

<Supplementary Note 13>

In the substrate processing apparatus of Supplementary note 12, preferably, further includes a state conversion unit including a third heating unit disposed outside the reaction tube, and when the reactant in a liquid state is supplied into the reaction tube, the reactant in a liquid state is converted into the reactant in a gaseous state in the reaction tube by the state conversion unit and flows in the reaction tube toward the exhaust unit.

<Supplementary Note 14>

In the substrate processing apparatus of Supplementary note 1, preferably, the reactant is vaporized outside the reaction tube to be in a gaseous state and supplied into the reaction tube.

<Supplementary Note 15>

According to still another aspect of the present invention, there is provided a substrate processing method including:
(a) loading a substrate into a reaction tube;
(b) processing the substrate; and
(c) unloading the substrate processed in the step (b) from the reaction tube; wherein the step (b) includes:
   (b-1) heating the substrate in the reaction tube by a first heating unit;
   (b-2) supplying a reactant in gaseous state to the substrate by a supply unit;
   (b-3) heating a downstream portion of the reactant in gaseous state flowing in the reaction tube from the supply unit toward an exhaust unit by a heat absorbing unit disposed in a furnace lid and heated by a second heating unit to maintain the downstream portion of the reactant in gaseous state.

<Supplementary Note 16>

According to still another aspect of the present invention, there is provided a method of manufacturing a semiconductor device including:
(a) loading a substrate into a reaction tube;
(b) processing the substrate; and
(c) unloading the substrate processed in the step (b) from the reaction tube; wherein the step (b) includes:
   (b-1) heating the substrate in the reaction tube by a first heating unit;
   (b-2) supplying a reactant in gaseous state to the substrate by a supply unit;
   (b-3) heating a downstream portion of the reactant in gaseous state flowing in the reaction tube from the supply unit toward an exhaust unit by a heat absorbing unit disposed in a furnace lid and heated by a second heating unit to maintain the downstream portion of the reactant in gaseous state.

<Supplementary Note 17>

In the method of Supplementary note 16, preferably, a temperature of the substrate is maintained at a predetermined processing temperature by the first heating unit, and the reactant is maintained in gaseous state by the second heating unit in the step (b).

<Supplementary Note 18>

In the method of Supplementary note 16, preferably, the heat absorbing unit is heated in the step (b) such that the reactant in a gap between the reaction tube and the furnace lid is maintained in gaseous state.

<Supplementary Note 19>

In the method of Supplementary note 16, preferably, an outer perimeter surface of the heat absorbing unit is disposed outer than an inner circumference surface of a lowe end portion of the reaction tube.

<Supplementary Note 20>

In the method of Supplementary note 16, preferably, an outer perimeter surface of the heat absorbing unit is disposed outer than an inner sidewall surface of the reaction tube.

<Supplementary Note 21>

In the method of Supplementary note 16, preferably, the heat absorbing unit is disposed inner than a sealing unit disposed in a gap between the reaction tube and the furnace lid.

<Supplementary Note 22>

According to still another aspect of the present invention, there is provided a program causing a computer to perform:
(a) loading a substrate into a reaction tube;
(b) processing the substrate; and
(c) unloading the substrate processed in the step (b) from the reaction tube;
wherein the sequence (b) includes:
   (b-1) heating the substrate in the reaction tube by a first heating unit;
   (b-2) supplying a reactant in gaseous state to the substrate by a supply unit;
   (b-3) heating a downstream portion of the reactant in gaseous state flowing in the reaction tube from the supply unit toward an exhaust unit by a heat absorbing unit disposed in a furnace lid and heated by a second heating unit to maintain the downstream portion of the reactant in gaseous state.

<Supplementary Note 23>

According to still another aspect of the present invention, there is provided a non-transitory computer-readable recording medium storing a program causing a computer to perform:
(a) loading a substrate into a reaction tube;
(b) processing the substrate; and
(c) unloading the substrate processed in the step (b) from the reaction tube; wherein the sequence (b) includes:
   (b-1) heating the substrate in the reaction tube by a first heating unit;
   (b-2) supplying a reactant in gaseous state to the substrate by a supply unit;
   (b-3) heating a downstream portion of the reactant in gaseous state flowing in the reaction tube from the supply unit toward an exhaust unit by a heat absorbing unit disposed in a furnace lid and heated by a second heating unit to maintain the downstream portion of the reactant in gaseous state.

<Supplementary Note 24>

According to still another aspect of the present invention, there is provided a furnace lid configured to cover a lower end portion of a reaction tube of a substrate processing apparatus including: the reaction tube where a substrate is processed; a first heating unit configured to heat the substrate in the reaction tube; and a second heating unit configured to heat a downstream portion of a reactant in gaseous state flowing in the reaction tube, the furnace lid including:

a heat absorbing unit being heated by the second heating unit.

<Supplementary Note 25>

In the furnace lid of Supplementary note 24, preferably, an outer perimeter surface of the heat absorbing unit is disposed outer than an inner circumference surface of the lower end portion.

<Supplementary Note 26>

In the furnace lid of Supplementary note 24, preferably, an outer perimeter surface of the heat absorbing unit is disposed outer than an inner side all surface of the reaction tube.

<Supplementary Note 27>

In the furnace lid of Supplementary note 24, preferably, the second heating unit is disposed at a lower portion of the reaction tube or at the furnace lid.

<Supplementary Note 28>

In the furnace lid of Supplementary note 24, preferably, the heat absorbing unit is disposed inner than a sealing unit disposed in a gap between the reaction tube and the furnace lid.

According to the substrate processing apparatus, the method of manufacturing the semiconductor device and the furnace lid of the present invention, by suppressing a re-liquefaction of a processing gas in a reaction tube, the processing gas in the reaction tube can be maintained in a gaseous state.

What is claimed is:

1. A substrate processing apparatus comprising:
a reaction tube where a substrate is processed;
a supply unit configured to supply a reactant to the substrate;
an exhaust unit configured to exhaust an inside atmosphere of the reaction tube;
a first heating unit configured to heat the substrate in the reaction tube;
a second heating unit configured to heat a downstream portion of the reactant in gaseous state flowing in the reaction tube from the supply unit toward the exhaust unit; and
a furnace lid configured to cover a lower end portion of the reaction tube, wherein the furnace lid comprises a heat absorbing unit facing a lower surface of the lower end portion and being heated by the second heating unit, the heat absorbing unit having an outer perimeter surface disposed outer than an inner circumference surface of the lower end portion.

2. The substrate processing apparatus of claim 1, further comprising a control unit configured to control the first heating unit to maintain a temperature of the substrate at a predetermined processing temperature, and control the second heating unit to maintain the reactant in gaseous state in the reaction tube.

3. The substrate processing apparatus of claim 1, further comprising a control unit configured to control the second heating unit to heat the heat absorbing unit such that the reactant in a gap between the reaction tube and the furnace lid is maintained in gaseous state.

4. The substrate processing apparatus of claim 1, wherein the outer perimeter surface of the heat absorbing unit is disposed outer than an inner sidewall surface of the reaction tube.

5. The substrate processing apparatus of claim 1, wherein the heat absorbing unit is disposed inner than a sealing unit disposed in a gap between the reaction tube and the furnace lid.

6. The substrate processing apparatus of claim 4, wherein the heat absorbing unit is disposed inner than a sealing unit disposed in a gap between the reaction tube and the furnace lid.

7. A method of manufacturing a semiconductor device, comprising:
(a) loading a substrate into a reaction tube;
(b) processing the substrate; and
(c) unloading the substrate processed in the step (b) from the reaction tube;
wherein the step (b) comprises:
(b-1) heating the substrate in the reaction tube by a first heating unit;
(b-2) supplying a reactant in gaseous state to the substrate by a supply unit;
(b-3) heating a downstream portion of the reactant in gaseous state flowing in the reaction tube from the supply unit toward an exhaust unit by a heat absorbing unit disposed in a furnace lid to face a lower surface of a lower end portion of the reaction tube and heated by a second heating unit to maintain the downstream portion of the reactant in gaseous state, the heat absorbing unit having an outer perimeter surface disposed outer than an inner circumference surface of the lower end portion.

8. The method of claim 7, wherein a temperature of the substrate is maintained at a predetermined processing temperature by the first heating unit, and the reactant is maintained in gaseous state by the second heating unit in the step (b).

9. The method of claim 7, wherein the heat absorbing unit is heated in the step (b) such that the reactant in a gap between the reaction tube and the furnace lid is maintained in gaseous state.

10. The method of claim 7, wherein the outer perimeter surface of the heat absorbing unit is disposed outer than an inner sidewall surface of the reaction tube.

11. The method of claim 7, wherein the heat absorbing unit is disposed inner than a sealing unit disposed in a gap between the reaction tube and the furnace lid.

12. A furnace lid configured to cover a lower end portion of a reaction tube of a substrate processing apparatus comprising: the reaction tube where a substrate is processed; a first heating unit configured to heat the substrate in the reaction tube; and a second heating unit configured to heat a downstream portion of a reactant in gaseous state flowing in the reaction tube, the furnace lid comprising:
a heat absorbing unit facing a lower surface of the lower end portion and being heated by the second heating unit, the heat absorbing unit having an outer perimeter surface disposed outer than an inner circumference surface of the lower end portion.

13. The furnace lid of claim 12, wherein the outer perimeter surface of the heat absorbing unit is disposed outer than an inner sidewall surface of the reaction tube.

14. The furnace lid of claim 12, wherein the heat absorbing unit is disposed inner than a sealing unit disposed in a gap between the reaction tube and the furnace lid.

15. The furnace lid of claim 13, wherein the heat absorbing unit is disposed inner than a sealing unit disposed in a gap between the reaction tube and the furnace lid.
